(19) United States
(12) Patent Application Publication
(10) Pub. No.: US 2025/0154658 A1
(43) Pub. Date: May 15, 2025

(54) ATOMIC LAYER ETCHING USING AN INHIBITOR

(71) Applicant: Lam Research Corporation, Fremont, CA (US)

(72) Inventors: Aaron Lynn ROUTZAHN, Fremont, CA (US); Andreas FISCHER, Castro Valley, CA (US); Thorsten LILL, Kalaheo, HI (US)

(21) Appl. No.: 18/840,069

(22) PCT Filed: Feb. 7, 2023
(86) PCT No.: PCT/US2023/062150

§ 371 Date: Aug. 20, 2024

Related U.S. Application Data
(60) Provisional application No. 63/268,366, filed on Feb. 22, 2022.

(51) Int. Cl. C23F 1/02; C23F 1/08

(52) U.S. Cl. CPC C23F 1/02; C23F 1/08

(57) ABSTRACT

Examples are provided related to using an inhibitor in an atomic layer etching process. One example provides a method for performing atomic layer etching of a substrate. The method comprises performing a plurality of etch cycles. At least one process cycle of the plurality of etch cycles comprises exposing the substrate to a modification chemical in a modification step, exposing the substrate to an inhibitor chemical, and exposing the substrate to a volatilization chemical in a removal step.

### BACKGROUND

Semiconductor device fabrication processes may involve many steps of material deposition, patterning, and removal to form integrated circuits on substrates. Various methods can be used to selectively remove material from a substrate. As an example, atomic layer etching (ALE) removes substrate material using one or more process cycles. In a process cycle, a modification step is used to modify a material at a film surface. Then, a removal step volatilizes and removes the modified film material. A highly uniform etch can be achieved via one or more ALE cycles.

### SUMMARY

This summary is provided to introduce a selection of concepts in a simplified form that are further described below in the Detailed Description. This summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to using an inhibitor chemical in an atomic layer etching (ALE) process. One example provides a method for performing ALE of a substrate. The method comprises performing a plurality of process cycles. At least one process cycle of the plurality of etch cycles comprises exposing the substrate to a modification chemical in a modification step, exposing the substrate to an inhibitor chemical, and exposing the substrate to a volatilization chemical in a removal step.

In some such examples, the substrate comprises a feature, wherein exposing the substrate to the modification chemical comprises exposing the feature to the modification chemical in a non-saturation regime.

In some such examples, exposing the substrate to the inhibitor chemical additionally or alternatively comprises exposing the substrate to a reactive inhibitor species generated by one or more of a remote plasma or an in-situ plasma.

In some such examples, the method additionally or alternatively further comprises heating the substrate while introducing the inhibitor chemical.

In some such examples, exposing the substrate to an inhibitor chemical additionally or alternatively comprises exposing the substrate to one or more of H₂, HCl, Cl₂, HBr, Br₂, HI, an oxidizing chemical, or a ligand.

In some such examples, the oxidizing chemical additionally or alternatively comprises one or more of oxygen, ozone, hydrogen peroxide, water vapor, nitric oxide, or nitrous oxide.

In some such examples, exposing the substrate to the modification chemical in the modification step additionally or alternatively comprises exposing the substrate to reactive species generated by a remote plasma comprising the modification chemical.

In some such examples, exposing the substrate to the volatilization chemical in the volatilization step additionally or alternatively comprises exposing the substrate to one of dimethylaluminum chloride, trimethyl aluminum, boron trichloride, trimethyl phosphine, silicon tetrachloride, titanium tetrachloride, acetyl-acetone, hexafluoro-acetylacetone, or tin (II)-acetylacetonate.

In some such examples, exposing the substrate to the modification chemical in the modification step additionally or alternatively comprises exposing the substrate to the modification chemical in a non-saturation regime.

In some such examples, the at least one process cycle comprises a first process cycle, and the plurality of process cycles additionally or alternatively comprises a second process cycle that omits exposing the substrate to the inhibitor chemical.

Another example provides a processing tool for performing atomic layer etching (ALE) on a substrate. The processing tool comprises a process chamber. The processing tool further comprises a substrate support disposed within the process chamber. The processing tool further comprises a substrate heater disposed within the process chamber. The processing tool further comprises one or more gas inlets into the process chamber. The processing tool further comprises flow control hardware configured to control gas flow through the one or more gas inlets. The processing tool further comprises a controller operatively coupled to the flow control hardware and the substrate heater. The controller is configured to control etching of a substrate supported by the substrate support. The controller is further configured to operate the substrate heater to heat the substrate. The controller is further configured to operate the flow control hardware to introduce a modification chemical into the process chamber in a modification step. The controller is further configured to operate the flow control hardware to introduce an inhibitor chemical into the process chamber. The controller is further configured to operate the flow control hardware to introduce a volatilization chemical into the process chamber in a removal step.

In some such examples, the processing tool further comprises an inhibitor gas source.

In some such examples, the inhibitor gas source additionally or alternatively comprises one or more of hydrogen gas, hydrogen chloride, chlorine gas, hydrogen bromide, bromine gas, hydrogen iodide, oxygen, ozone, hydrogen peroxide, water vapor, nitric oxide, nitrous oxide, or a ligand.

In some such examples, the processing tool additionally or alternatively comprises a remote plasma generator, and the controller is configured to operate the remote plasma generator to generate reactive inhibitor species.

In some such examples, the controller is additionally or alternatively configured to expose the substrate to the modification chemical within a non-saturation regime.

In some such examples, the controller is additionally or alternatively configured to perform a plurality of process cycles, at least one process cycle of the plurality of process cycles omitting introduction of the inhibitor chemical into the process chamber.

Another example provides a computer-readable storage device comprising instructions executable by a computing device comprising a processor to control a processing tool to operate flow control hardware of the processing tool to introduce a modification chemical into a process chamber of the processing tool in a modification step. The instructions are further executable to control the processing tool to operate the flow control hardware to introduce an inhibitor gas into the process chamber. The instructions are further executable to control the processing tool to operate the flow control hardware to introduce a volatilization chemical into the process chamber in a removal step.

In some such examples, the instructions executable to operate the flow control hardware to introduce an inhibitor gas into the process chamber additionally or alternatively comprise instructions executable to operate the flow control hardware to introduce one or more of hydrogen gas, hydrogen chloride, chlorine gas, hydrogen bromide, bromine gas, hydrogen iodide, oxygen, ozone, hydrogen peroxide, water vapor, nitric oxide, nitrous oxide, or a ligand into the process chamber.

In some such examples, the instructions executable to operate the flow control hardware to introduce the modification chemical in the modification step additionally or alternatively comprise instructions executable to operate the flow control hardware to introduce the modification chemical into the process chamber in a non-saturation regime.

In some such examples, the instructions are additionally or alternatively executable to operate the flow control hardware to introduce the inhibitor chemical into a remote plasma generator.

### BRIEF DESCRIPTION OF THE DRAWINGS

FIG. 1 shows a block diagram of an example processing tool.

FIG. 2 shows a flow diagram depicting an example method for performing an atomic layer etching (ALE) process.

FIG. 3 shows a flow diagram depicting an example method for performing a process cycle that comprises introduction of an inhibitor chemical.

FIG. 4 shows a flow diagram depicting an example method for performing a process cycle that omits introduction of an inhibitor chemical.

FIGS. 5A-5C schematically show an example substrate structure, and illustrate a portion of a feature before and after performing an ALE process.

FIGS. 6A-C schematically show results of etching a feature using different example ALE processes.

FIG. 7 shows a flow diagram depicting an example method for etching a surface in a feature.

FIG. 8 schematically shows an example computing device.

### DETAILED DESCRIPTION

The term “aspect ratio” represents a ratio between the depth or height of a substrate feature and a width of a substrate feature.

The term “atomic layer etching” (ALE) represents a process in which an etchable material on a substrate is removed in one or more cycles by sequentially modifying the material surface and removing the modified material species. An ALE process may comprise alternating self-limiting chemical reactions that affect surface atomic layer(s) of a substrate. One example ALE process etches hafnia (HfO₂) by fluorinating the hafnium (Hf) using hydrogen fluoride (HF) to form fluorinated hafnium, and volatilizing the fluorinated hafnium, for example in the form of HfF₄ or HfFₓO_{y}, using dimethyl aluminum chloride (DMAC).

The term “etchable material” represents a substrate surface that can be modified and volatilized for removal via an ALE process. Example etchable materials include hafnium oxide (hafnia), silicon-doped hafnia, hafnium-zirconium oxide, tungsten oxide, hafnium silicates, aluminum oxide, zirconium oxide, indium oxide, silicon, silicon dioxide, gallium oxide, zinc oxide, indium-gallium-zinc-oxide (InGaZnO), indium-gallium arsenide (InGaAs), indium-aluminum-arsenide (InAlAs), aluminum (Al), cobalt (Co), copper (Cu), gallium (Ga), germanium (Ge), hafnium (Hf), indium (In), iron (Fe), nickel (Ni), tungsten (W), vanadium (V), zinc (Zn), zirconium (Zr), and silicon-germanium (SeGe) of various Ge concentrations (e.g. Ge from 0-100%).

The term “feature” represents a recess or prominence on a substrate surface. Examples of features include trenches (e.g. slots), holes (e.g. vias of any suitable shape), and pillars.

The term “inhibitor chemical” represents a chemical species that inhibits chemical etching within an ALE process. An inhibitor chemical may inhibit etching via various mechanisms, such as slowing down a reaction rate, blocking a reaction site, and/or reversing a reaction step. In various examples, the inhibitor chemical may comprise an oxidant, a hydrogen-containing chemical, and/or a halogen-containing chemical. Example inhibitor chemicals include hydrogen (H₂), hydrogen chloride (HCl), chlorine (Cl₂), hydrogen bromide (HBr), bromine (Br₂), hydrogen iodide (HI), water (H₂O), hydrogen peroxide (H₂O₂), oxygen (O₂), ozone (O₃), nitric oxide (NO), nitrous oxide (N₂O), and ligands, including bidentate ligands. Example ligands include acetylacetone (ACAC), and diamines such as ethylenediaminetetraacetic acid (EDTA), tetramethylethylenediamine (TMEDA), and 1,3-diaminopropane.

The term “intermediate structure” represents a structure formed by earlier processing steps that is modified in later processing steps.

The term “modification chemical” represents a chemical species that is used as part of an process cycle to chemically alter a substrate material surface. Modification of the surface may comprise fluorination, halogenation, hydrogenation, hydroxylation, oxidation, or other suitable chemical modification. In ALE, surface modification precedes removal by volatilization of the modified material species. Example modification chemicals include hydrogen fluoride (HF), fluorine (F₂), xenon difluoride (XeF₂), and nitrogen trifluoride (NF₃).

The term “non-saturation regime” represents processing conditions in which a chemical species does not fully saturate surfaces of a substrate.

The term “process chamber” represents an enclosure in which chemical and/or physical processes are performed on substrates. The pressure, temperature and atmospheric composition within a process chamber may be controllable to perform chemical and/or physical processes.

The term “processing tool” represents a machine comprising a process chamber and other hardware configured to enable processing to be carried out on a substrate.

The terms “purge” and variants thereof represent processes in which unwanted species are removed from a process chamber.

The term “reactive inhibitor species” represents radicals and other activated species formed by the introduction of an inhibitor chemical into a plasma.

The term “saturation regime” represents processing conditions in which a chemical species is allowed to saturate surfaces on a substrate.

The term “substrate” represents any object from which a layer or material can be etched.

The term “substrate support” represents any structure for supporting a substrate in a process chamber. Example substrate supports include pedestals and chucks.

The term “uniform” and variants thereof represent uniformity within a desired tolerance range.

The term “volatilization chemical” represents a chemical that can react with a modified substrate surface to volatilize substrate material species for removal via a vacuum and/or a process chamber purge. Example volatilization chemical include dimethylaluminum chloride (DMAC), trimethyl aluminum (TMA), boron trichloride, trimethylphosphine, silicon tetrachloride, titanium tetrachloride, acetyl-acetone, hexafluoro-acetylacetone, and tin (II)-acetylacetonate. The term “metal volatilization chemical” represents a chemical that can react with an oxidized metal for removal of the metal. Example metal volatilization chemicals include titanium tetrachloride (TiCl₄), dimethylacetamide (DMAc), dimethylaluminum chloride (AlMe₂Cl), acetylacetone, and acetylacetonates.

The term “3D DRAM” is an acronym for three-dimensional dynamic random-access memory.

The term “3D NAND” is an acronym for three-dimensional NOT AND memory, and represents memory architecture based upon NOT AND logic gates.

The term “3D NOR” is an acronym for three-dimensional NOT OR memory, and represents memory architecture based upon NOT OR logic gates.

As mentioned above, an ALE process involves performing one or more process cycles to remove one or more layers from a substrate surface. ALE may be used to remove material from an intermediate structure as part of a semiconductor manufacturing process. During an process cycle, a modification step is performed in which a modification chemical is introduced into a process chamber comprising a substrate. The modification chemical reacts with one or more atomic layers of the substrate surface to form a modified surface. For example, a substrate may be exposed to HF to form a fluorinated surface. Then, a removal step is performed in which a volatilization chemical is introduced into the process chamber. The volatilization chemical volatilizes at least some of the modified substrate material, thereby removing material from the substrate surface. The volatilized material can then be removed from the process chamber. Repeated process cycles in which the modification chemical saturates the substrate surface can be performed to remove a selected amount of substrate material in a highly uniform manner.

However, uniformly etching some features on a substrate may pose challenges. For example, some features comprise relatively narrow widths and/or high aspect ratios. Gas diffusion to the bottom of a high aspect ratio feature may be a relatively slow process. As mentioned above, etching using ALE is generally achieved by operating within a saturation regime of the modification chemical. However, performing ALE within a saturation regime on a high aspect ratio feature may be slow, in view of the relatively long time it can take for the modification chemical (as well as other process chemicals) to saturate surfaces deeper within a feature.

Accordingly, examples are disclosed that relate to using an inhibitor chemical in an ALE process. As described below, in some examples an inhibitor chemical can be used to achieve highly uniform etching of high aspect ratio features within a non-saturation regime of the modification chemical.

One example process in which uniform etching may be challenging is an oxide film etch within channel holes in a 3D NAND memory fabrication process. In such a process, the sidewalls of the channel hole comprise alternating layers of different materials. A film of etchable material applied during a previous step may be etched via an ALE process to form gate oxide structures. If the gate oxide thickness is inconsistent as a function of channel hole depth, device performance may suffer. For example, a gate oxide that is too thick may result in a high switching voltage, whereas a gate oxide that is too thin may cause an electrical short. Thus, to form gate oxides with consistent thickness, a uniform etch as a function of depth is desired. However, as the channel holes may have relatively high aspect ratios, achieving such a uniform etch by operating within a saturation regime for the modification chemical may take a significant amount of time. Furthermore, the feature may comprise reentrant structures and/or overhanging shelves such that a target etching surface is in a non-line-of-sight location relative to a feature opening.

Operating in a non-saturation regime to reduce processing time can cause nonuniform etching. For example, within a non-saturation regime, the surface modification chemical may have a concentration profile in the channel holes that is depth-dependent. In the case of a NAND gate oxide etch, concentrations of the modification chemical may be higher closer to a channel hole opening, and lower farther from the channel hole opening. This may lead to higher etching rates within the channel hole closer to the opening, and lower etching rates deeper within the channel hole. This can result in uneven gate oxide thicknesses. Such nonuniform concentrations also can cause nonuniform film thickness in processes other than gate oxide etches . . .

Thus, as described in more detail below, an inhibitor chemical may be used to inhibit one or more of the modification reaction and volatilization reaction in an ALE process. The inhibitor chemical may be deposited in the non-saturation regime, resulting in a depth-dependent concentration profile. Higher concentrations of the inhibitor chemical closer to an opening of the feature helps to reduce the higher rate of etching that would otherwise be caused by the higher concentration of the modification chemical. As a result, more uniform rates of etching may be achieved, even when introducing the modification chemical in a non-saturation regime. In other examples, a saturation regime may be used, or a mix of non-saturation and saturation regimes in different process cycles during an ALE process.

In some examples, an inhibitor chemical may be directly introduced into a process chamber. In other examples, a remote plasma may be used to generate reactive inhibitor species from the inhibitor chemical. In such examples, the reactive inhibitor species may undergo surface reactions and recombine to reduce a concentration of active species as the active species diffuse towards the bottom of the feature. This may result in a higher concentration of inhibitor chemical adsorbing to surfaces within a feature closer the feature opening than to surfaces deeper within the feature. Again, this may help to reduce the rate of etching that would otherwise occur due to the higher concentration of modification chemical closer to the feature opening. As a result, more uniform etching may be achieved. Example ALE processes are disclosed in more detail below.

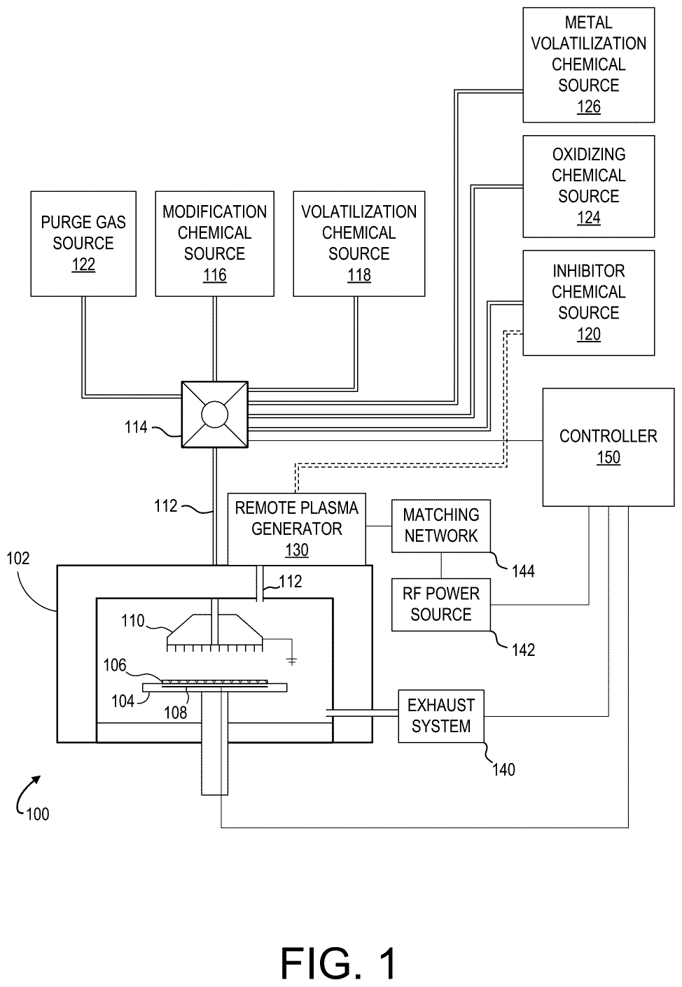

FIG. 1 shows a schematic view of an example processing tool 100 for performing ALE using an inhibitor chemical. Processing tool 100 comprises a process chamber 102 and a substrate support 104 within the process chamber. Substrate support 104 is configured to support a substrate 106 disposed within process chamber 102. Substrate support 104 may comprise a pedestal, a chuck, or any other suitable structure. Process chamber 102 further may include a substrate heater 108.

Processing tool 100 further comprises a showerhead 110, a gas inlet 112, and flow control hardware 114. In other examples, a processing tool may comprise a nozzle or other apparatus for introducing gas into process chamber 102, as opposed to or in addition to a showerhead. Flow control hardware is connected to a modification chemical source 116, a volatilization chemical source 118, an inhibitor chemical source 120, and a purge gas source 122. In some examples, flow control hardware 114 is further connected to an oxidizing chemical source 124 and a metal volatilization chemical source 126. Modification chemical source 116 may comprise any suitable modification chemical that, when exposed to an etchable material, modifies the material surface. Suitable modified surfaces may include fluorinated metal oxide surfaces, fluorinated boron oxide surfaces, or other surfaces that can be volatilized by a volatilization chemical. Example modification chemicals include HF, F₂, XeF₂, and NF₃.

Volatilization chemical gas source 118 comprises any suitable chemical that can react with a modified substrate surface to volatilize substrate material species. For example, in examples where HfO₂ is being etched with HF, example volatilization chemicals include dimethylaluminum chloride (DMAC), trimethyl aluminum (TMA), boron trichloride, trimethylphosphine, silicon tetrachloride, titanium tetrachloride, acetyl-acetone, hexafluoro-acetylacetone, and tin (II)-acetylacetonate.

Inhibitor chemical source 120 comprises any suitable chemical species that inhibits etching in an ALE process. The inhibitor chemical inhibits etching by affecting a conversion step prior to volatilization. The inhibitor chemical may inhibit etching via any suitable mechanism, such as slowing down a reaction rate, blocking a reaction site, or reversing a reaction step. In some examples, the inhibitor chemical may comprise an oxidant, a hydrogen-containing chemical, and/or a halogen-containing chemical. A chemical inhibitor comprising an oxidant can react with a fluorinated surface to convert the fluorinated surface back to a metal oxide. A hydrogen-containing chemical can be used to hydrogenate the substrate surface and block fluorination sites. A halogen-containing chemical (e.g., HCl, Cl₂, HBr, Br₂) can be used to halogenate the surface (e.g., chlorinate or brominate the surface) and block fluorination sites. In still further examples, a ligand can be used to block fluorination sites via chemisorption or physisorption. Blocking reaction sites slows down the fluorination reaction, rather than fully impeding the reaction. In some examples, the inhibitor chemical may persist on the substrate for one or more additional process cycles. Example inhibitor chemicals include H₂, HCl, Cl₂, HBr, Br₂, HI, H₂O, H₂O₂, O₂, O₃, NO, N₂O, and ligands. Example ligands include acetylacetone (ACAC), and diamines such as ethylenediaminetetraacetic acid (EDTA), tetramethylethylenediamine (TMEDA), and 1,3-diaminopropane.

In some examples, substrate heater 108 is used to provide thermal energy to activate one or more reactions in an ALE process. In other examples, a remote plasma is generated via a remote plasma generator 130 to produce reactive inhibitor species, in addition or alternatively to heating the substrate. The remote plasma may form reactive inhibitor species from an inhibitor chemical. In such examples, inhibitor chemical source 120, as well as one or more other gas sources, may be connected to remote plasma generator 130. Remote plasma generator 130 is optional, and may be omitted in some examples.

Purge gas source 122 may comprise any suitable inert gas, such as argon or nitrogen. In some examples, one or more additional purge gas sources may be included, each providing a different purge gas.

Oxidizing chemical source 124, where included, may comprise any suitable oxidizing gas. Examples include O₂, O₃, N₂O, H₂O, and H₂O₂.

Likewise, metal volatilization chemical source 126 may comprise any suitable chemical for volatilizing an oxidized metal layer. Examples include titanium tetrachloride (TiCl₄), dimethylacetamide (DMAc), dimethylaluminum chloride (AlMe₂Cl), acetylacetone, and acetylacetonates.

Flow control hardware 114 may be controlled to flow a chemical from chemical sources 116, 118, 120, 122, 124, 126 into process chamber 102 via gas inlet 112. In some examples, flow control hardware is also configured to control the flow of one or more chemicals into remote plasma generator 130. Flow control hardware 114 schematically represents any suitable components related to flowing gas into process chamber 102 (and remote plasma generator 130 in some examples). For example, flow control hardware 114 may comprise one or more mass flow controllers and/or valves controllable to place a selected chemical source in fluid connection with gas inlet 112. As mentioned above, flow control hardware 114 further may be connected to an oxidizing chemical source 124 and metal volatilization chemical source 126 For example, in a first configuration, flow control hardware 114 may place modification chemical source 116 in fluid connection with gas inlet 112 such that the modification chemical flows into process chamber 102. In a second configuration, flow control hardware 114 may place volatilization chemical source 118 in fluid connection with gas inlet 112 to allow the volatilization chemical to flow into process chamber 102. In a third configuration, flow control hardware 114 may place inhibitor chemical source 120 in fluid connection with gas inlet 112 to allow the oxidizable inhibitor chemical to flow into process chamber 102. In a fourth configuration, flow control hardware 114 may place purge gas source 122 in fluid connection with gas inlet 112 to allow the purge gas to flow into process chamber 102. In some examples, in a fifth configuration, flow control hardware 114 may place oxidizing chemical source 124 in fluid connection with gas inlet 112 to allow the oxidizing chemical to flow into process chamber 102. In some examples, in a sixth configuration, flow control hardware 114 may place metal volatilization chemical source 126 in fluid connection with gas inlet 112 to allow the metal volatilization chemical to flow into process chamber 102. In yet further configurations, flow control hardware 114 may place two or more of such chemical sources in fluid communication with gas inlet 112.

Processing tool 100 further comprises an exhaust system 140. Exhaust system 140 is configured to receive gas outflowing from process chamber 102 including volatilized substrate species. In some examples, exhaust system 140 is configured to actively remove gas from process chamber 102 and/or apply a partial vacuum. Exhaust system 140 may comprise any suitable hardware, including one or low vacuum pumps and/or one or more high vacuum pumps.

Where optional remote plasma generator 130 is used, processing tool 100 may further comprise a radiofrequency power source 142 electrically connected to remote plasma generator 130. In other examples, radiofrequency power source 142 may supply radiofrequency power to substrate support 104, showerhead 110, or to other suitable electrode structure to perform in situ plasma processing. Processing tool 100 further may include a matching network 144 for impedance matching of the radiofrequency power source 142. Radiofrequency power source 142 may be configured for any suitable frequency and power. Examples of suitable frequencies include 400 kHz, 13.56 MHZ, 27 MHz, 60 Mz, and 90 MHz. Examples of suitable powers include powers between 50 W (watts) and 50 kW. In some examples, radiofrequency power source 142 is configured to operate at a plurality of different frequencies and/or powers.

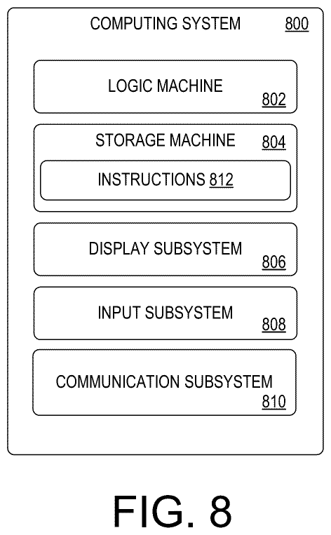

Controller 150 is operatively coupled to substrate heater 108, flow control hardware 114, remote plasma generator 130, exhaust system 140, and radiofrequency power source 142. Controller 150 further may be operatively coupled to any other suitable component of processing tool 100. Controller 150 is configured to control various functions of processing tool 100 to perform an ALE process. For example, controller 150 is configured to operate substrate heater 108 to heat a substrate. Controller 130 is also configured to operate flow control hardware 114 to flow a selected chemical or mixture of chemicals at a selected rate into process chamber 102. Controller 150 is also configured to operate exhaust system 140 to remove gases from process chamber 102. Controller 150 is further configured to operate flow control hardware 114 and exhaust system 140 to maintain a selected pressure within process chamber 102. Furthermore, controller 150 is configured to operate remote plasma generator 130 and/or radiofrequency power source 142 to form a remote plasma comprising the inhibitor chemical, as well as control any other functions of processing tool 100. Controller 150 may comprise any suitable computing system, examples of which are described below with reference to FIG. 8.

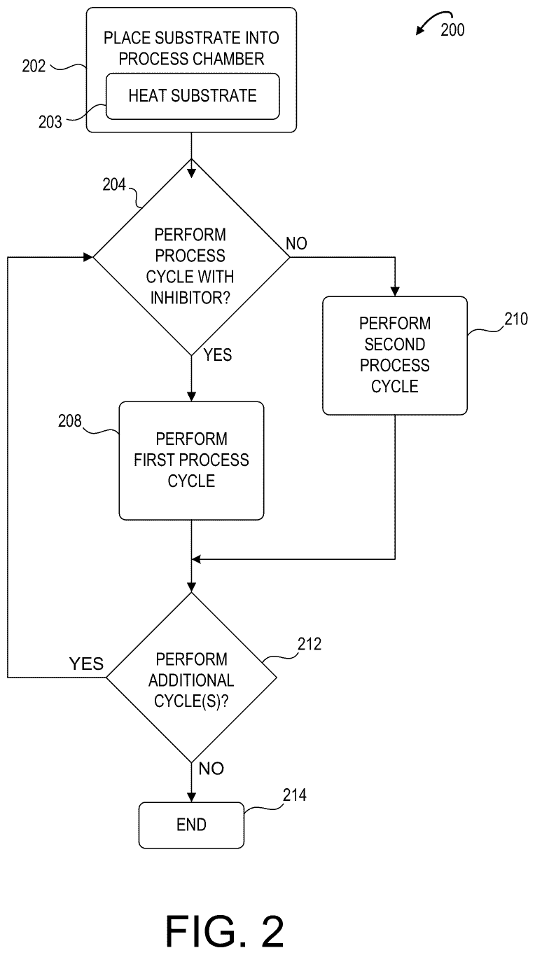

FIG. 2 shows a flow diagram of an example method 200 for etching a substrate. Method 200 may be performed, for example, using processing tool 100. Method 200 comprises, at 202, placing a substrate into a process chamber. In some examples, method 200 may comprise heating the substrate via a substrate heater, as indicated at 203. The substrate may comprise a feature. Any suitable substrate may be used. Examples include semiconductor wafers. The surface of the substrate and/or feature may comprise any suitable etchable material. Example etchable materials include hafnia, silicon-doped hafnia, hafnium-zirconium oxide, tungsten oxide, hafnium silicates, aluminum oxide, zirconium oxide, indium oxide, silicon, silicon dioxide, gallium oxide, zinc oxide, indium-gallium-zinc-oxide (InGaZnO), indium-gallium arsenide (InGaAs), indium-aluminum-arsenide (InAlAs), aluminum (Al), cobalt (Co), copper (Cu), gallium (Ga), germanium (Ge), hafnium (Hf), indium (In), iron (Fe), nickel (Ni), tungsten (W), vanadium (V), zinc (Zn), zirconium (Zr), and silicon-germanium (SeGe) of various Ge concentrations (e.g. Ge from 0-100%).

The features formed in the substrate may comprise any suitable intermediate structure in an integrated circuit fabrication process. For example, the features may be formed in a 3D NAND, 3D DRAM, or 3D NOR fabrication process.

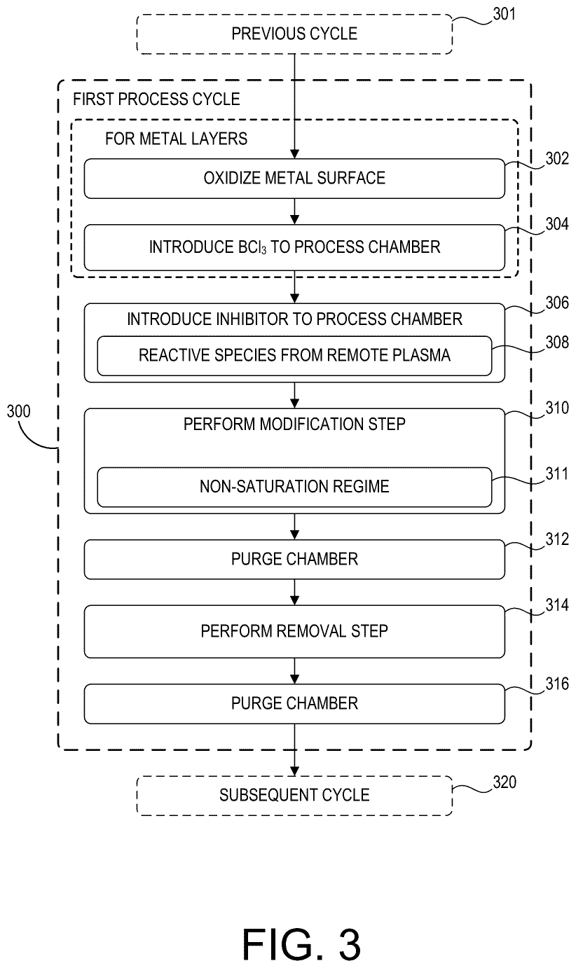

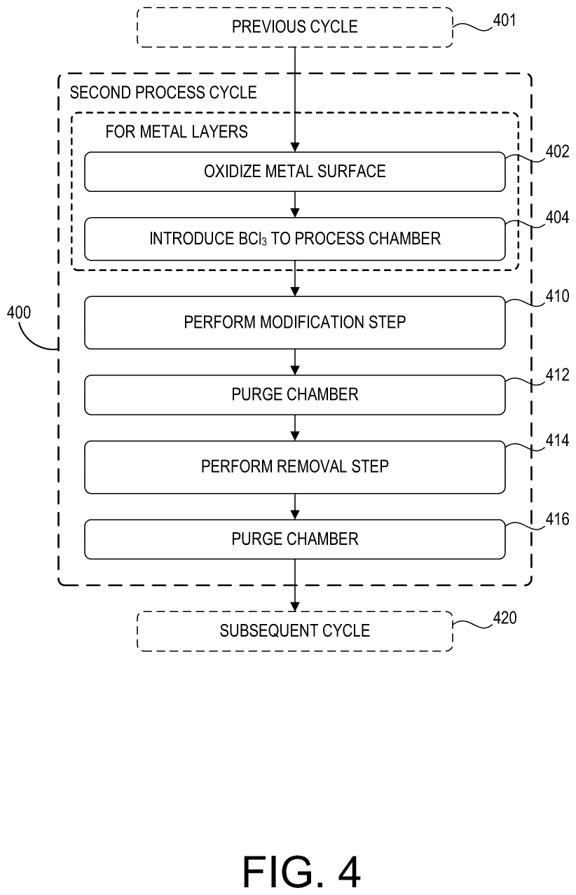

Method 200 further comprises, at 204, determining whether to perform an process cycle comprising an inhibitor gas or an process cycle omitting the inhibitor gas. The determination may be based upon a recipe for a specific process being performed. The term “first process cycle” is used herein to represent an atomic layer process cycle that includes introduction of an inhibitor chemical. An example first process cycle is shown in FIG. 3. The term “second process cycle” is used herein to represent an atomic layer process cycle that omits introduction of an inhibitor chemical. An example second process cycle is shown in FIG. 4. As described in more detail below, a ratio of first process cycles to second process cycles can be varied to control a degree of uniformity of the etch. Additionally or alternatively, a duration of exposure of the inhibitor chemical to the substrate can be varied to control the degree of uniformity of the etch. In some examples, the degree of uniformity of an etch may be controlled based on operating conditions within a process chamber or a characteristic of a feature. Example operating conditions include temperature and pressure. Example feature characteristics include an aspect ratio of the feature, a depth of a feature, material compositions within the feature, a reactivity of the material in the feature with the inhibitor chemical, and whether a feature has reentrant characteristics.

FIG. 3 shows a flow diagram depicting an example first process cycle 300 for etching a substrate disposed in a process chamber. First process cycle 300 includes introducing an inhibitor chemical. An instance of first process cycle 300 can follow a previous process cycle 301, which can be a first process cycle 300 or a second process cycle 400.

In some examples, first process cycle 300 may comprise etching a metal layer. Examples of metal layers include Al, Co, Cu, Ga, Ge, Hf, In, Fe, Ni, W, V, Zn, and Zr. For metal layers, first process cycle 300 comprises oxidizing the metal surface at 302. For example, an oxidizing chemical may be introduced to the process chamber. Examples of oxidizing chemicals include O₂, O₃, N₂O, H₂O, and H₂O₂. Additionally, for metal layers, first process cycle 300 comprises introducing BCl₃ to the process chamber at 304. BCl₃ reacts with the oxidized metal surface to volatilize the metal species, leaving boron oxide at the surface. In other examples, materials other than BCl₃ may be used to volatilize an oxidized metal. Examples include titanium tetrachloride (TiCl₄), dimethylacetamide (DMAc), dimethylaluminum chloride (AlMe₂Cl), acetylacetone, and acetylacetonates. In other examples that do not involve etching metal layers, first process cycle 300 may omit 302 and 304.

First process cycle 300 comprises, at 304, introducing an inhibitor chemical to the process chamber. As discussed above, the inhibitor chemical may affect one or more reaction steps prior to volatilization of substrate material species. For example, the inhibitor chemical may be selected to inhibit fluorination of the surface, react with surface F, or displace and/or remove F from the surface. The inhibitor chemical may comprise an oxidant, a hydrogen-containing chemical, a halogen-containing chemical, or other suitable inhibitors, including mixtures thereof. Example inhibitor chemicals include H₂, HCl, Cl₂, HBr, Br₂, HI, H₂O, H₂O₂, O₂, O₃, NO, N₂O, and ligands. Example ligands include ACAC, diamines such as ethylenediaminetetraacetic acid, tetramethylethylenediamine, and 1,3-diaminopropane. In some examples, HCl is used to chlorinate the substrate surface and block fluorination sites prior to introducing a modification chemical. In some examples that utilize a fluorine-containing modification chemical, H₂O₂ or other suitable compound may be used to oxidize and remove F from the substrate surface following fluorination but prior to introducing the volatilization chemical.

In some examples the inhibitor chemical is introduced via a showerhead or nozzle while heating the substrate. In such examples, the inhibitor chemical may be introduced in the non-saturation regime, thereby adsorbing to substrate surfaces non-uniformly. For example, inhibitor chemical deposited in a substrate feature may comprise a higher concentration closer to a feature opening than farther from the feature opening.

In other examples, at 308, reactive inhibitor species generated in a remote plasma are introduced to the process chamber. The reactive inhibitor species may be formed by introducing the inhibitor chemical into a remote plasma generator. As reactive inhibitor species move farther into the feature, the reactive species may undergo a greater degree of surface reaction. This may reduce a concentration of reactive inhibitor species as a function of feature depth. Thus, the inhibition effect may be greater closer to the feature opening and lesser near the bottom of the feature. Reactive species formed by a remote plasma may be deposited in a saturated or unsaturated regime in various examples.

The use of a remote plasma to provide reactive species to the substrate may allow a lower substrate temperature to be used. This may help to avoid thermal degradation of the substrate, the modification chemical, the volatilization chemical, and/or other chemical species. In yet other examples, any other suitable energy source may be used. Further, in some examples, in-situ plasmas can be used, such as an inductively coupled plasma (ICP). As an in-situ plasma may have a directional kinetic energy component, a lower power in-situ plasma may be more favorable than a higher power in-situ plasma to avoid directional etching effects.

First process cycle 300 further comprises, at 310, performing a modification step comprising introducing a modification chemical to the process chamber. In some examples, the modification chemical comprises HF. HF can react with various surface materials to fluorinate a substrate surface layer. Other examples of modification chemicals include F₂, XeF₂, and NF₃. Example substrate surface materials include hafnia, silicon-doped hafnia, hafnium-zirconium oxide, tungsten oxide, hafnium silicates, aluminum oxide, zirconium oxide, indium oxide, silicon, silicon dioxide, gallium oxide, zinc oxide, indium-gallium-zinc-oxide (InGaZnO), indium-gallium arsenide (InGaAs), indium-aluminum-arsenide (InAlAs), and silicon-germanium (SeGe) of various Ge concentrations (e.g., Ge from 0-100%). In examples where 302 and 304 are performed to etch a metal layer, the modification chemical can react with the boron oxide on the substrate surface. In some examples, at 311, the modification chemical is introduced to the process chamber in a non-saturation regime. Additionally or alternatively, in some examples, a remote plasma generator is used to introduce reactive modification chemical species generated by a remote plasma. In any of such examples, a concentration gradient of modification chemical may be on feature sidewalls, with higher concentrations closer to the feature opening and lower concentrations farther from the feature opening. The inhibitor chemical may have a similar concentration gradient. Thus, the inhibitor chemical may help counter etching rate differences caused by the depth-dependent concentration gradient of the modification chemical. This may result in an etching rate that is relatively consistent with depth. In some examples, the inhibitor chemical may be introduced following introduction of the modification chemical. Further, in some examples, the inhibitor chemical may be introduced following introduction of the volatilization chemical. In yet other examples, the inhibitor chemical is introduced together with the modification chemical. In further examples, the inhibitor chemical may be introduced at any other suitable location in a process cycle.

First process cycle 300 further comprises an optional purge of the process chamber at 312. Purging the chamber may be performed using a purge gas.

Continuing, first process cycle 300 further comprises performing a removal step comprising introducing a volatilization chemical to the process chamber at 314. The volatilization chemical reacts with the modified substrate surface to volatilize substrate material species. Volatilized species are then be removed from the process chamber via a purge at 316. Example volatilization chemicals include dimethylaluminum chloride (DMAC), trimethyl aluminum (TMA), boron trichloride, trimethylphosphine, silicon tetrachloride, titanium tetrachloride, acetyl-acetone, hexafluoro-acetylacetone, and tin (II)-acetylacetonate. The volatilization chemical may be selected based on an effectiveness in volatilizing the substrate material species. In some examples, the substrate is heated via a substrate heater during processing. In some examples, the substrate may be heated to a temperature within a range of 100° C. to 400° C. In other examples, substrate temperatures outside of this range may be used.

First process cycle may be performed any suitable number of times during the processing of a substrate. First process cycle may precede a subsequent cycle 320, which may be a first process cycle 300 or second process cycle 400.

FIG. 4 shows a flow diagram depicting an example second process cycle 400 that omits introducing an inhibitor chemical. An instance of second process cycle 400 can follow a previous process cycle 301. Previous process cycle 301 can be a first process cycle 300 or a second process cycle 400.

In some examples, second process cycle 400 may comprise etching a metal layer. For metal layers, second process cycle 400 comprises oxidizing the metal surface at 402. For example, an oxidizing chemical may be introduced to the process chamber. Additionally, for suitable metal layers, second process cycle 400 comprises introducing BCl₃ or other suitable metal volatilization chemical to the process chamber at 404. BCl₃ reacts with the oxidized metal surface to volatilize metal species, leaving boron oxide at the surface. In other examples that do not involve etching a metal layer, second process cycle 400 may omit 402 and 404.

Second process cycle 400 further comprises, at 410, performing a modification step comprising introducing a modification chemical to the process chamber. In some examples, the modification chemical comprises HF, which reacts with the substrate to fluorinate the substrate surface layer. Other examples of modification chemicals again include F₂, XeF₂, and NF₃. In some examples, at 411, the modification chemical is introduced to the process chamber within a non-saturation regime. In such examples, the modification chemical does not saturate and modify high aspect ratio sidewalls of features. While second process cycle 400 omits introducing an inhibitor chemical, the modification reaction at 410 may still be inhibited by an inhibitor chemical adsorbed during a previous process cycle 401 in some examples. The modification step may be used to modify any suitable substrate surface. Examples include those listed above with regard to first process cycle 300.

Second process cycle 400 further comprises an optional purge of the process chamber at 412. Purging the chamber may be performed using a purge gas and/or removing gas from the process chamber via an exhaust system.

Continuing, second process cycle 400 further comprises performing a removal step comprising introducing a volatilization chemical to the process chamber at 414. After modifying the substrate surface at 410 in the modification step, the volatilization chemical reacts with the modified substrate surface to volatilize substrate material species. Volatilized species are then be removed from the process chamber via a purge at 416.

Second process cycle 400 may be performed zero or more times during the processing of a substrate. Second process cycle 400 may precede a subsequent cycle 420, which may be a first process cycle 300 or second process cycle 400. Second process cycle 400 may be interspersed with first process cycle 300 in any suitable order and at any suitable frequency.

Returning to FIG. 2, when it is determined to run an process cycle comprising introduction of an inhibitor chemical, method 200 comprises performing a first process cycle at 208. As mentioned above, first process cycle 300 of FIG. 3 is an example of the first process cycle performed at 208. Likewise, when it is determined at 204 to run an process cycle without introducing an inhibitor chemical, method 200 comprises performing a second process cycle at 210. As mentioned above, second process cycle 400 of FIG. 4 is an example of the second process cycle performed at 210.

At 212, method 200 may perform additional process cycles, e.g., according to an overall recipe for processing a substrate. If additional process cycles are to be performed, method 200 returns to 204. Additional process cycles may result in a greater amount of material etched from the substrate. When a target amount of substrate material has been removed by etching, method 200 may proceed from 212 to 214 and terminate.

The relative proportion of process cycles with an inhibitor chemical to process cycles without an inhibitor may be varied based on factors such as a desired amount of uniformity in the etch and/or a characteristic of a feature. For example, an ALE process may comprise performing n first process cycles 300 followed by m second process cycles 400. The numbers n and m may be any suitable integers. These steps may be repeated any suitable number of times. In such examples, the proportion P of process cycles which include introducing the inhibitor chemical may be determined by

$$P = \frac{n}{n + m} .$$

In some examples, n and m may vary during the processing of a substrate.

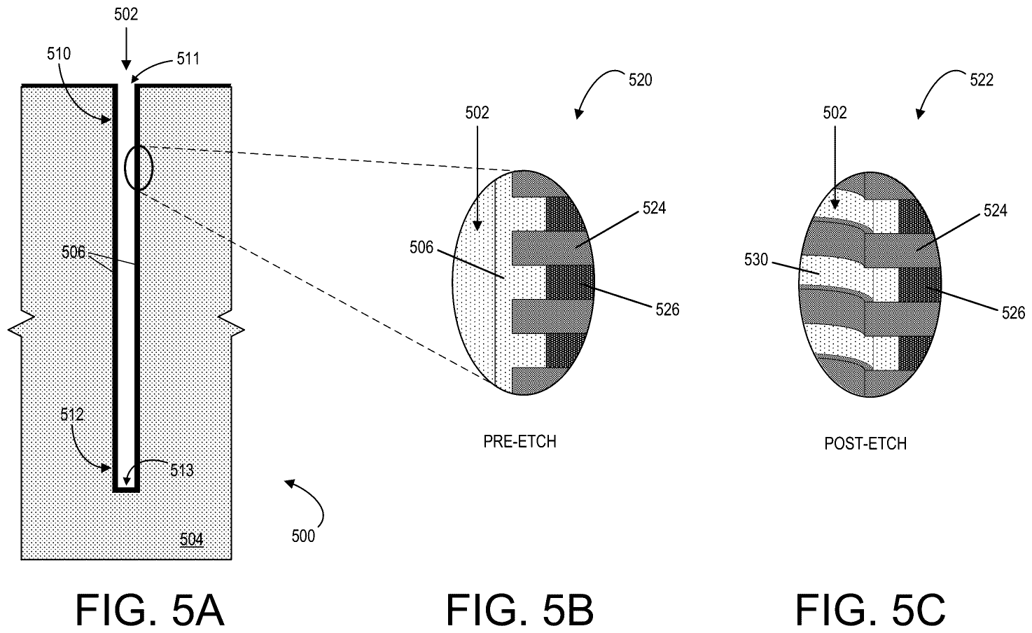

FIG. 5A schematically shows an intermediate structure 500. Intermediate structure represents any suitable structure formed at an intermediate stage in an integrated circuit fabrication process. Intermediate structure 500 comprises a feature 502 in substrate 504. Substrate 504 comprises a layer of etchable material 506. Etchable material 506 may comprise a metal, a metal oxide, silicon, silicon oxide, or other suitable substrate material. Feature 502 may comprise a relatively high aspect ratio. For example, feature 502 may comprise an aspect ratio within a range of 20:1 to 100:1 in some examples. In other examples, a feature may have an aspect ratio outside of this example range. It will be understood that feature 502 and other substrate features depicted herein may not be drawn to scale.

Feature 502 comprises low aspect ratio sidewall surfaces 510 relatively closer to an opening of the feature 511. Feature 502 further comprises high aspect ratio sidewall surfaces 512 relatively closer to a bottom of the feature 513.

In some examples, substrate 504 may comprise a 3D NAND structure. Such an example structure is depicted in a cut-away schematic view in pre-etch form in FIG. 5B at 520 and in post-ALE form in FIG. 5C at 522. As shown at 520, the 3D NAND structure comprises alternating silicon oxide layers 524 and silicon nitride layers 526. In other examples, a 3D integrated circuit structure may comprise alternating oxide/polysilicon layers, or any other suitable structure.

As shown at 520, feature 502 comprises sidewalls comprising a layer of etchable material 506. In some examples, etchable material 506 comprises hafnia.

The post-etch view of FIG. 5C shows the 3D NAND structure after performing an ALE process. A portion of hafnia has been removed, leaving behind another portion that forms a gate oxide 530 for a transistor. In other examples, etchable material 506 may comprise any suitable material for use in a 3D NAND structure. As shown in FIG. 5C, gate oxide 530 is disposed under an overhanging oxide layer in a non-line-of-sight location within feature 502.

As discussed above, it may be challenging to uniformly etch material from within a high aspect ratio feature. For example, when performing a modification step on a substrate comprising a high aspect ratio feature, the modification chemical may saturate the bottom of the feature slowly. Full saturation of the modification chemical (or volatilization chemical) within the feature may take a relatively long time, which may slow down overall substrate processing. On the other hand, performing ALE within a non-saturation regime without an inhibitor chemical may result in more nonuniform etching of high aspect ratio features. This may result in inconsistent gate oxide thicknesses, with some gates requiring a higher turn-on voltage and others presenting shorting risks.

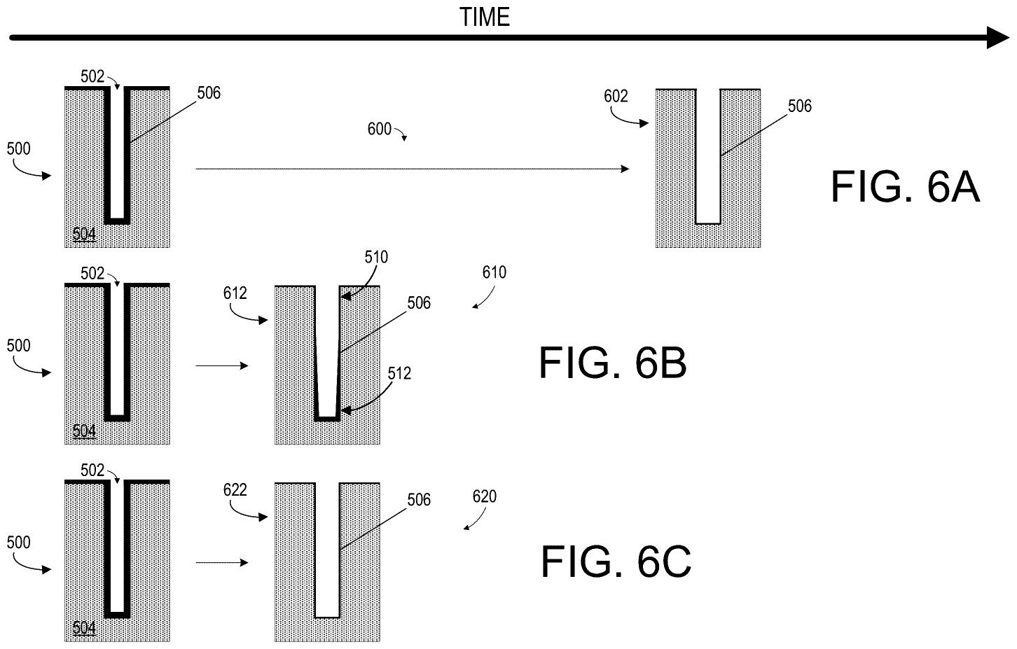

Thus, the use of an inhibitor chemical as described above, may allow a suitably uniform etch of feature 502 to be performed more efficiently. The term “suitably uniform” indicates uniformity within a tolerance range. FIGS. 6A-6C schematically compare etching of intermediate structure 500 using three different example etching processes. The time axis of FIGS. 6A-6C is qualitative and may not represent quantitative differences between process times.

Process 600 of FIG. 6A illustrates performing ALE within a saturation regime of the modification chemical and omits introducing an inhibitor chemical. Process 600 results in a relatively uniform etch of etchable material 506 within feature 502. However, process 600 is relatively slow, and the resultant intermediate structure 602 is achieved after a greater time.

Process 610 of FIG. 6B illustrates performing ALE within a non-saturation regime. Further, process 610 omits introducing an inhibitor chemical. Due to slower etch rates at high aspect ratio sidewall surfaces, etchable material 506 is not etched uniformly. As shown at 612, etchable material 506 remains relatively thicker at high aspect ratio sidewall surfaces 512. A relatively thick layer of etchable material 506 may lead to difficulties in further device processing and/or operational problems of the integrated circuits being fabricated. For example, if etchable material 506 is etched to a suitable thickness at 510, the thickness at 512 may be too thick. Similarly, it etchable material 506 is etched to a suitable thickness at 512, the thickness at 510 may be too thin, as described above.

Next, process 620 of FIG. 6C illustrates performing ALE that includes the introduction of an inhibitor chemical. Process 620 may be performed within a non-saturation regime of the modification chemical. Thus, process 620 may be completed in a relatively shorter amount of time compared to process 600. As shown at 622, etchable material 506 within feature 502 is etched relatively uniformly.

As mentioned above, a ratio of a number of process cycles comprising introduction of an inhibitor to a number of process cycles omitting the inhibitor may be selected to etch with a desired degree of uniformity. Additionally or alternatively, a duration of inhibitor chemical exposure to the substrate may be selected to achieve a desired degree of etch uniformity. The ratio and/or exposure duration may be selected based upon any suitable factors, such as an aspect ratio of a feature, a depth of a feature, an etchable material within the feature, whether a feature has reentrant features, and/or other factors.

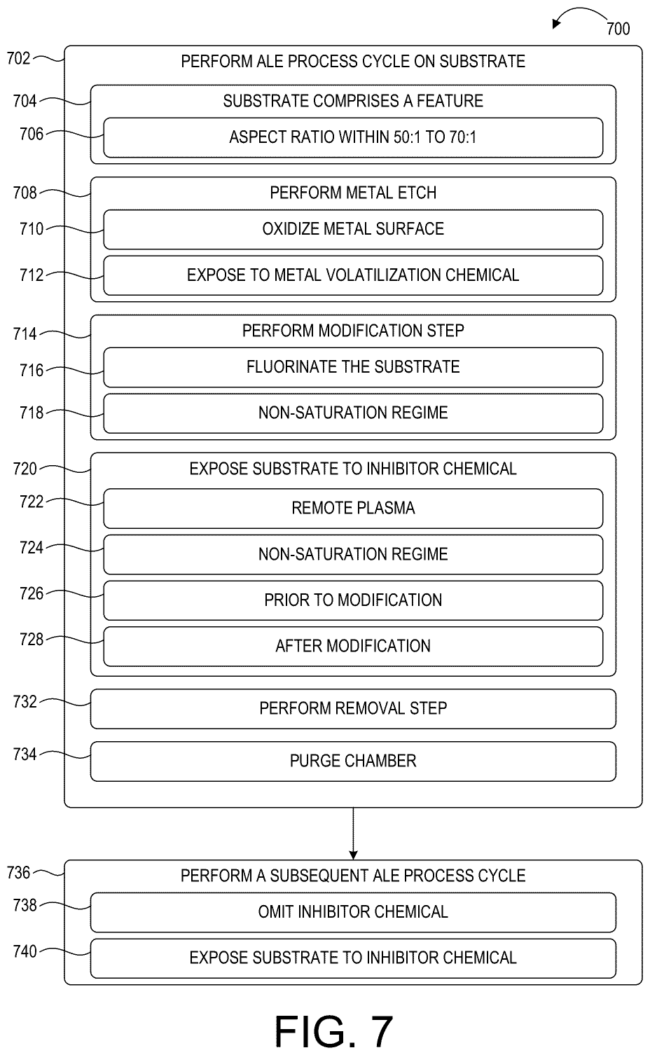

FIG. 7 shows a flow diagram of an example method 700 for performing an ALE process. At 702, the method comprises performing at least one process cycle on a substrate. In some examples, a plurality of process cycles are performed. First process cycle 300 and second process cycle 400 are examples of process cycles. In some examples, at 704, the substrate comprises a feature. In some examples, at 706, the feature comprises a relatively high aspect ratio, such as within a range of 50:1 to 70:1. In other examples, the feature may comprise an aspect ratio outside of this range.

Continuing method 700, performing process cycle 702 may comprise performing a metal etch at 708. In such examples, at 710, performing a metal etch comprises oxidizing a surface of a metal layer. In such examples, performing the metal etch further comprises, at 712, exposing the oxidized metal surface to a metal volatilization chemical. Examples include BCl₃, TiCl₄, dimethylacetamide, dimethylaluminum chloride, acetylacetone, and acetylacetonates. Such compounds may be used to volatilize the oxidized metal species and form boron oxide on the surface. Suitable metals may include Hf, W, Al, Zr, In, and Ga.

In some examples, method 700 may omit performing a metal etch at 708, e.g., when etching oxides or other materials. Examples of substrate materials that may be etched via ALE as disclosed comprise hafnia, silicon-doped hafnia, hafnium-zirconium oxide, tungsten oxide, hafnium silicates, aluminum oxide, zirconium oxide, indium oxide, silicon, silicon dioxide, gallium oxide, zinc oxide, indium-gallium-zinc-oxide (InGaZnO), indium-gallium arsenide (InGaAs), indium-aluminum-arsenide (InAlAs), and silicon-germanium (SeGe) of various Ge concentrations (e.g. Ge from 0-100%). In examples where 710 and 712 are performed to etch a metal layer, the surface may comprise boron oxide and/or other boron-containing compounds.

At 714, method 700 further comprises performing a modification step. The modification step comprises exposing the substrate to a modification chemical. In some examples, the modification chemical comprises fluorine. Examples of such modification chemicals include HF, NF₃, XeF₂ and F₂. In such examples, method 700 comprises fluorinating the substrate at 716. In some examples, when a metal etch is performed, fluorinating the substrate at 716 comprises fluorinating a boron oxide surface formed at 712. In some examples, at 718, the modification chemical is exposed to the substrate within a non-saturation regime.

Continuing, at 720 the method further comprises exposing the substrate to an inhibitor chemical. In some examples, at 722, the method comprises introducing reactive inhibitor species generated by a remote plasma into the process chamber. Alternatively or additionally, in some examples, at 724, the inhibitor chemical may be introduced directly into process chamber in a non-saturation regime. In some examples, at 726, the substrate is exposed to the inhibitor chemical prior to exposing the substrate to the modification chemical. In some examples, at 728, the substrate is exposed to the inhibitor chemical after exposing the substrate to the modification chemical. In some examples, the substrate is exposed to the inhibitor chemical both before and after the modification chemical. In some examples, the inhibitor chemical is introduced to the process chamber together with the modification chemical. Further, in some examples, the inhibitor chemical is introduced into the process chamber after introduction of the volatilization chemical. In some examples, the inhibitor chemical comprises one or more of H₂, HCl, Cl₂, HBr, Br₂, HI, H₂O, H₂O₂, O₂, O₃, NO, N₂O, and ligands, including bidentate ligands.

Method 700 may optionally comprise performing one or more purges following 714 and/or following 720.

At 732, method 700 comprises performing a removal step. The removal step comprises exposing the substrate to a volatilization chemical. In some examples, the volatilization chemical comprises one of dimethylaluminum chloride (DMAC), trimethyl aluminum (TMA), boron trichloride, trimethylphosphine, silicon tetrachloride, titanium tetrachloride, acetyl-acetone, hexafluoro-acetylacetonate, or tin (II)-acetylacetonate. Then, at 734, the removal step further comprises purging the process chamber to remove substrate species volatilized at 732.

Method 700 may further comprise, at 736, performing one or more subsequent process cycles. In some examples, at 738, the subsequent cycle comprises a second process cycle and omits exposing the substrate to the inhibitor. In some examples, at 740, the subsequent cycle comprises a first process cycle and comprises exposing the substrate to the inhibitor chemical.

Thus, the examples disclosed herein may provide for an efficient, uniform etch of a substrate comprising a high aspect ratio feature. While disclosed in the contexts of features with relatively high aspect ratios, the disclosed examples can be used to etch any suitable substrate comprising any suitable features. For example, the disclosed examples can also be used to etch non-line-of-sight substrate surfaces, such as sidewalls in features with reentrant structures, below overhanging shelves in 3D NAND structures, pillar sidewalls, or around nanowires in gate-all-around (GAA) structures.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 8 schematically shows a non-limiting embodiment of a computing system 800 that can enact one or more of the methods and processes described above. Computing system 800 is shown in simplified form. Computing system 800 may take the form of one or more personal computers, workstations, computers integrated with wafer processing tools, and/or network accessible server computers.

Computing system 800 includes a logic machine 802 and a storage machine 804. Computing system 800 may optionally include a display subsystem 806, input subsystem 808, communication subsystem 810, and/or other components not shown in FIG. 8. Controller 150 is an example of computing system 800.

Logic machine 802 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 804 includes one or more physical devices configured to hold instructions 812 executable by the logic machine to implement the methods and processes described herein. When such methods and processes are implemented, the state of storage machine 804 may be transformed—e.g., to hold different data.

Storage machine 804 may include removable and/or built-in devices. Storage machine 804 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 804 may include volatile, nonvolatile, dynamic, static, read/write, read-only, random-access, sequential-access, location-addressable, file-addressable, and/or content-addressable devices.

It will be appreciated that storage machine 804 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 802 and storage machine 804 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 806 may be used to present a visual representation of data held by storage machine 804. This visual representation may take the form of a graphical user interface (GUI). As the herein described methods and processes change the data held by the storage machine, and thus transform the state of the storage machine, the state of display subsystem 806 may likewise be transformed to visually represent changes in the underlying data. Display subsystem 806 may include one or more display devices utilizing virtually any type of technology. Such display devices may be combined with logic machine 802 and/or storage machine 804 in a shared enclosure, or such display devices may be peripheral display devices.

When included, input subsystem 808 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 810 may be configured to communicatively couple computing system 800 with one or more other computing devices. Communication subsystem 810 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 800 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for performing atomic layer etching of a substrate, the method comprising:
performing a plurality of process cycles, at least one process cycle of the plurality of process cycles comprising
exposing the substrate to a modification chemical in a modification step,
exposing the substrate to an inhibitor chemical, and
exposing the substrate to a volatilization chemical in a removal step.

2. The method of claim 1, wherein the substrate comprises a feature, and wherein exposing the substrate to the modification chemical comprises exposing the feature to the modification chemical in a non-saturation regime.

3. The method of claim 1, wherein exposing the substrate to the inhibitor chemical comprises exposing the substrate to a reactive inhibitor species generated by one or more of a remote plasma or an in-situ plasma.

4. The method of claim 1, further comprising heating the substrate while introducing the inhibitor chemical.

5. The method of claim 1, wherein exposing the substrate to an inhibitor chemical comprises exposing the substrate to one or more of H₂, HCl, Cl₂, HBr, Br₂, HI, an oxidizing chemical, or a ligand.

6. The method of claim 5, wherein the oxidizing chemical comprises one or more of H₂O, H₂O₂, O₂, O₃, NO, and N₂O.

7. The method of claim 1, wherein exposing the substrate to a modification chemical comprises exposing the substrate to reactive species generated by a remote plasma comprising the modification chemical.

8. The method of claim 1, wherein exposing the substrate to a volatilization chemical comprises exposing the substrate to one of more of dimethylaluminum chloride, trimethyl aluminum, boron trichloride, trimethylphosphine, silicon tetrachloride, titanium tetrachloride, acetyl-acetone, hexafluoro-acetylacetone, or tin (II)-acetylacetonate.

9. The method of claim 1, wherein exposing the substrate to the modification chemical in the modification step comprises exposing the substrate to the modification chemical in a non-saturation regime.

10. The method of claim 1, wherein the at least one process cycle comprises a first process cycle, and wherein the plurality of process cycles further comprises a second process cycle that omits exposing the substrate to the inhibitor chemical.

11. A processing tool for performing atomic layer etching on a substrate, the processing tool comprising:
a process chamber;
a substrate support disposed within the process chamber;
a substrate heater disposed within the process chamber;
one or more gas inlets into the process chamber;
flow control hardware configured to control gas flow through the one or more gas inlets; and
a controller operatively coupled to the flow control hardware and the substrate heater, the controller configured to control etching of a substrate supported by the substrate support, the controller configured to
operate the substrate heater to heat the substrate,
operate the flow control hardware to introduce a modification chemical into the process chamber in a modification step,
operate the flow control hardware to introduce an inhibitor chemical into the process chamber, and
operate the flow control hardware to introduce a volatilization chemical into the process chamber in a removal step.

12. The processing tool of claim 11, further comprising an inhibitor gas source.

13. The processing tool of claim 12, wherein the inhibitor gas source comprises one or more of hydrogen gas, hydrogen chloride, chlorine gas, hydrogen bromide, bromine gas, hydrogen iodide, oxygen, ozone, hydrogen peroxide, water vapor, nitric oxide, nitrous oxide, or a ligand.

14. The processing tool of claim 11, further comprising a remote plasma generator, and wherein the controller is configured to operate the remote plasma generator to generate reactive inhibitor species.

15. The processing tool of claim 11, wherein the controller is configured to expose the substrate to the modification chemical within a non-saturation regime.

16. The processing tool of claim 11, wherein the controller is configured to perform a plurality of process cycles, at least one process cycle of the plurality of process cycles omitting introduction of the inhibitor chemical into the process chamber.

17. A computer-readable storage device comprising:
instructions executable by a computing device comprising a processor to control a processing tool to
operate flow control hardware of the processing tool to introduce a modification chemical into a process chamber of the processing tool in a modification step
operate the flow control hardware to introduce an inhibitor gas into the process chamber,
operate the flow control hardware to introduce a volatilization chemical into the process chamber in a removal step.

18. The computer-readable storage device of claim 17, wherein the instructions executable to operate the flow control hardware to introduce an inhibitor gas into the process chamber comprise instructions executable to operate the flow control hardware to introduce one or more of hydrogen gas, hydrogen chloride, chlorine gas, hydrogen bromide, bromine gas, hydrogen iodide, oxygen, ozone, hydrogen peroxide, water vapor, nitric oxide, nitrous oxide, or a ligand into the process chamber.

19. The computer-readable storage device of claim 17, wherein the instructions executable to operate the flow control hardware to introduce the modification chemical in the modification step comprise instructions executable to operate the flow control hardware to introduce the modification chemical into the process chamber in a non-saturation regime.

20. The computer-readable storage device of claim 17, wherein the instructions are executable to operate the flow control hardware to introduce the inhibitor chemical into a remote plasma generator.
